(19) United States
(12) Patent Application Publication
(10) Pub. No.: US 2002/0047141 A1
(43) Pub. Date: Apr. 25, 2002

(54) Semiconductor device, and manufacture thereof

(75) Inventor: Akinobu Teramoto, Tokyo (JP)

Correspondence Address: McDermott, Will & Emery, 600 13th Street, N.W., Washington, DC, 20005-3096, US

(73) Assignee: MITSUBISHI DENKI KABUSHIKI KAISHA

(21) Appl. No.: 09/797,737

(22) Filed: Mar. 5, 2001

(30) Foreign Application Priority Data
Sep. 7, 2000 (JP) 2000-271025

(51) Int. Cl. H01L 29/04

(52) U.S. Cl. 257/288

(57) ABSTRACT

A semiconductor device easily attains a higher degree of integration and stable quality. Agate insulating film is formed so as to cover the side surfaces and bottom of a gate electrode. A pair of source/drain regions are provided by way of the gate insulating film such that the gate electrode is interposed between the source/drain regions. A channel region is formed below the gate electrode by way of the gate insulating film. The surface of the gate electrode and the surfaces of the source/drain regions are made flush with each other.

### BACKGROUND OF THE INVENTION

1. Field of the Invention

The present invention relates to a semiconductor device and a method of manufacturing the semiconductor device, and more particularly, to a semiconductor device having a construction suitable for attaining a high degree of integration and stable quality, as well as to a method of manufacturing the semiconductor device.

2. Description of the Background Art

FIG. 6 is a cross-sectional view of a transistor provided in a conventional semiconductor device. The transistor shown in FIG. 6 has a silicon substrate including a p-type well 10 (hereinafter referred to simply as a “p-well”) . Agate insulating film 12 is formed on the surface of the p-well 10, and a gate electrode 14 is formed from polysilicon on the gate insulating film 12. A channel region 15 containing a low concentration of p-type impurities is formed in a position below the gate electrode 14. A sidewall 16 is formed from SiN on each side of the gate electrode 14.

A source-drain region 18 of lightly-doped drain (LDD) structure is formed in the p-well 10. The source-drain region 18 comprises a low-concentration n-type region 20 including a low concentration of n-type impurities, and a high-concentration n-type region 22 including a high concentration of n-type impurities.

The low-concentration n-type region 20 is formed by means of introducing n-type impurities into the p-well after formation of a gate electrode 14 on the gate insulation film 12. The high-concentration n-type region 22 is formed by means of implanting n-type impurities into the p-well 10 after formation of the sidewall 16 on each side of the gate electrode 14. During the course of manufacture of a transistor, after the p-well 10 has been doped with impurities, the entire silicon substrate is subjected to predetermined heat treatment in order to activate the impurities.

After heat treatment, an interlayer insulating film 24 is formed so as to cover the gate electrode 14 and the sidewalls 16. Further, a contact hole is formed in the interlayer insulating film 24, and a desired contact plug 26 is formed in the contact hole, thus constituting the construction shown in FIG. 6.

As mentioned above, the conventional semiconductor device has the gate electrode 14 on the silicon substrate which includes the source-drain region 18. In other words, the gate electrode 14 and the sidewalls 16 of the conventional semiconductor device protrude upward from the layer including the source-drain region 18. In this case, the space between adjacent gate electrodes 14 must be filled with the interlayer insulating film 20.

In association with an increase in the degree of integration of a semiconductor device, embedding the space between the adjacent gate electrodes 14 with the interlayer insulating film 20 becomes difficult. In this respect, the construction of the conventional semiconductor device involves a problem in ensuring stable quality with an increase in the degree of integration.

As mentioned above, according to a method of manufacturing a conventional semiconductor device, after formation of the gate insulating film 12 and the gate electrode 14, the substrate is subjected to heat treatment for the purpose of activating impurities. In such a case, the properties of the gate insulating film 12 and those of the gate electrode 14 may be degraded under influence of the heat treatment. Even in this regard, the structure of the conventional semiconductor device and the method of manufacturing a conventional semiconductor device involve a problem in ensuring stable quality.

### SUMMARY OF THE INVENTION

The present invention has been conceived to solve the problem and is aimed at providing a semiconductor device having a construction suitable for readily attaining a high degree of integration and stable quality.

The present invention is aimed at providing a method of manufacturing a semiconductor device of stable quality under circumstances where demand exists for a higher degree of integration.

The above mentioned objects of the present invention is achieved by a semiconductor device described below. The semiconductor device includes a gate electrode. The side surfaces and bottom surface of the gate electrode is covered by a gate insulating film. A pair of source/drain regions are provided by way of the gate insulating film such that the gate electrode is interposed between the source/drain regions. The semiconductor device also includes a channel region formed below the gate electrode with the gate insulating film therebetween. The surface of the gate electrode and the surfaces of the source/drain regions constitute a single flat surface.

The above mentioned objects of the present invention is also achieved by

The above mentioned objects of the present invention is achieved by a method of manufacturing a semiconductor device described below. In the method, a first-type well is formed by means of implanting impurities of first conductivity type into a silicon substrate. Source/drain regions are formed by means of implanting impurities of second conductivity type into the first-type well to a predetermined depth. A trench is formed in the first-type well so as to be sandwiched between the source/drain regions, by means of removing predetermined portions of the source/drain regions. A gate insulating film is formed so as to cover the side surfaces of the trench and the surface of the first-type well exposed on the bottom of the trench. Conductive material is embedded in the trench covered with the gate insulating film. A gate electrode in the trench is formed by means of removal of the portion of the conductive material existing out of the trench. An interconnection layer is formed on a layer to which the source/drain regions and the gate electrode pertain.

Other objects and further features of the present invention will be apparent from the following detailed description when read in conjunction with the accompanying drawings.

### BRIEF DESCRIPTION OF THE DRAWINGS

FIG. 1 is a cross-sectional view of a semiconductor device according to a first embodiment of the present invention;

FIGS. 2 and 3 are cross-sectional views for describing a manufacturing method of the semiconductor device according to the first embodiment;

FIG. 4 is a cross-sectional view of a modified example of the semiconductor device according to the first embodiment of the present invention;

FIG. 5 is a cross-sectional view of a semiconductor device according to a second embodiment of the present invention; and

FIG. 6 is a cross-sectional view of a conventional semiconductor device.

### DESCRIPTION OF THE PREFERRED EMBODIMENTS

A preferred embodiment of the present invention will be described hereinbelow by reference to the accompanying drawings. Throughout the drawings, common elements are assigned the same reference numerals, and repetition of their explanations is omitted.

First Embodiment

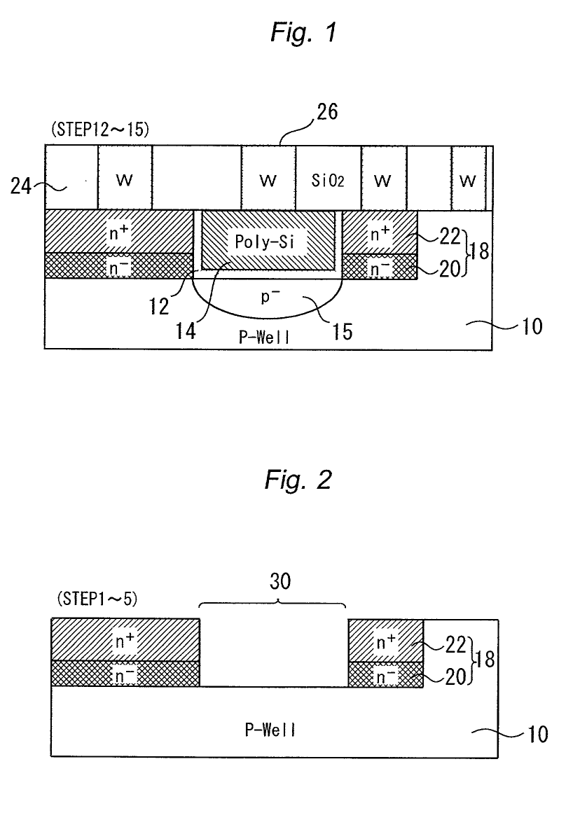

FIG. 1 is a cross-sectional view of a MOSFET included in a semiconductor device according to a first embodiment of the present invention. The MOSFET shown in FIG. 1 has a silicon substrate including a p-type well 10 (hereinafter referred to simply as a “p-well”) . The p-well 10 has a source-drain region 18 which comprises a low-concentration n-type region 20 containing a low concentration of n-type impurities and a high-concentration n-type region 22 containing a high concentration of n-type impurities. In the present invention, the low-concentration n-type region 20 is formed in a lower-layer area of the source-drain region 18, and the high-concentration n-type region 22 is formed in an upper-layer area of the same.

In the p-well 10, a trench of the same depth as the source/drain region 18 is formed in a position sandwiched between the two source/drain regions 18. A channel region 15 containing a low concentration of p-type impurities is formed in a position below the trench. Further, in the trench is formed a gate insulating film 12 covering the side surfaces of the source/drain region 18 and the surface of the channel region 15, and a gate electrode 14 is formed from polysilicon in the space defined by the gate insulating film 12. In the present embodiment, the gate insulating film 12 and the gate electrode 14 are formed such that the surface of the gate insulating film 12 and the surface of the gate electrode 14 form a single plane together with the surface of the source/drain region 18. In other words, the gate insulating film 12 and the gate electrode 14 are embedded in the p-well 10 so as not to protrude from the surface of the source/drain region 18.

An interlayer insulating film 24 is formed on the entire surface of the p-well 10 to substantially uniform thickness. A plurality of contact holes are formed in the interlayer insulating film 24. Contact plugs 26 are formed in the respective contact holes; some communicate with the source/drain region 18, some communicate with the gate electrode 14, and some communicate with the p-well 10.

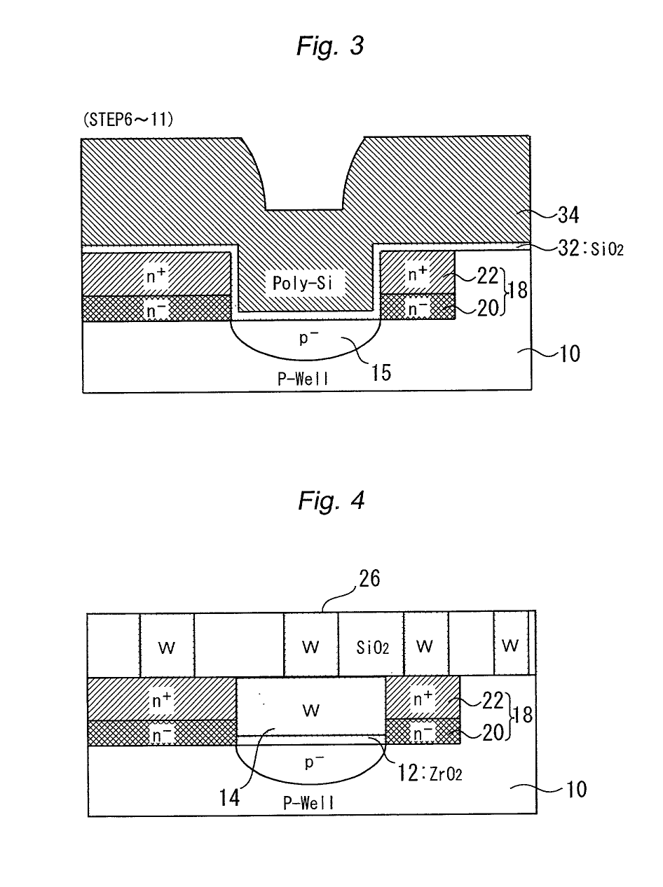

A method of manufacturing a MOSFET according to the present embodiment will now be described by reference to FIGS. 2 and 3.

FIG. 2 is a cross-sectional view showing a state, which the silicon substrate assumes after being subjected to processing steps 1 through 5 described below during the course of manufacture of the MOSFET shown in FIG. 1.

(Step 1) According to the manufacturing method of the present embodiment, an unillustrated shallow trench isolation (STI) structure is first formed on the silicon substrate in order to divide active regions each of which corresponds to an individual MOSFET.

(Step 2) P-type impurities are implanted into each of the thus-divided active regions divided by the STI structure, thereby constituting the p-well 10.

(Step 3) N-type impurities are implanted into a predetermined area of the p-well 10; that is, an area where the source/drain region 18 is to be formed, to a first depth, thus forming the low-concentration n-type region 20.

(Step 4) N-type impurities are implanted to the low-concentration n-type region 20 to a second depth shallower than the first depth, thus forming the high-concentration n-type region 22.

(step 5) A trench 30 in which the gate electrode 14 would be embedded is formed in a predetermined area of the p-well 10 by means of an isotropic etching, such that the bottom of the trench 30 becomes equal in depth with the bottom surface of the low-concentration n-type region 20.

Processing pertaining to steps 6 through 12 described below is performed after the foregoing processing, whereby the silicon substrate assumes a construction shown in FIG. 3.

(Step 6) The silicon substrate is subjected to predetermined heat treatment, and an unillustrated pad oxide film is formed over the entire surface of the silicon substrate to a thickness of about 10 nm.

(Step 7) P-type impurities are implanted into the trench 30 from above the pad oxide film, thereby forming a channel region 15.

(Step 8) The pad oxide film is removed by means of wet etching employing hydrofluoric (HF) acid, thereby further cleaning the surface of the silicon substrate.

(Step 9) The semiconductor substrate is subjected to heat treatment required for activating the impurities implanted in the source/drain region 18 and those implanted in the channel region 15. Before formation of the gate insulating film 12 and the gate electrode 14, the semiconductor substrate may be subjected to heat treatment at any timing. As mentioned above, in the present embodiment heat treatment for activating the impurities implanted in the source/drain region 18 and those implanted in the channel region 15 can be completed at another timing before formation of the gate insulating film 12 and the gate electrode 14.

(Step 10) Subsequent to the foregoing round of processing steps, a silicon oxide film 32 which is to be formed into the gate insulating film 12 is formed over the entire surface of the silicon substrate.

(Step 11) Polysilicon 34 is deposited on the entire surface of the silicon substrate so as to fill the trench 30.

The silicon substrate assumes a construction shown in FIG. 1 as a result of processing pertaining to steps 12 through 15 described below.

(Step 12) The polysilicon 34 and the silicon oxide film 32 are removed from the silicon substrate, with exception of the inside of the trench 30, by means of etch-back. As a result, the gate insulating film 12 and the gate electrode 14, which form a single plane together with the source/drain region 18 are formed within the trench 30.

(Step 13) The interlayer insulating film 24 is deposited on the silicon substrate by means of CVD.

(Step 14) Contact holes are formed in the interlayer insulating film 24; some communicate with the source/drain region 18; some communicate with the gate electrode 14; and some communicate with the p-well 10.

(Step 15) The inside of each contact hole is filled with metal material such as tungsten, thereby forming the contact plug 26.

As mentioned above, the structure of the semiconductor device according to the present embodiment and the method of manufacturing the semiconductor device can protect the gate insulating film 12 and the gate electrode 14 from high-temperature thermal load. Consequently, there can be prevented deterioration of the gate insulating film 12, which would otherwise be caused by thermal load, thus enabling implementation of a semiconductor device of stable quality.

Further, the structure of the semiconductor device according to the present embodiment and the method of manufacturing the semiconductor device can make the surface of the gate electrode 14 and the surface of the source/drain region 18 to be an identical plane. In this case, since the interlayer insulating film 24 is deposited on a flat surface, an appropriate state can be readily attained even when a MOSFET has a high degree of integration. Thus, the structure of the semiconductor device according to the present embodiment and the method of manufacturing the semiconductor device can readily ensure high equality even when a semiconductor device has a high degree of integration.

Under the method of manufacturing a semiconductor device according to the present embodiment, the gate insulating film 12 and the gate electrode 14 are formed by means of total etch-back of the polysilicon 34 and the silicon oxide film 32. The manufacturing method is not limited to the method mentioned previously; for example, the gate insulating film 12 and the gate electrode 14 may be formed by means of removal of the polysilicon 34 or the silicon oxide film 32 through CMP.

In the first embodiment, the gate insulating film 12 is formed from silicon oxide (SiO₂) . However, the material of the gate insulating film 12 is not limited to silicon oxide. More specifically, according to the present embodiment, no high temperature is applied to the gate insulating film 12. Hence, material whose dielectric constant is higher than that of SiO₂; for example, Al₂03 or ZrO₂, maybe used. In such a case, as compared with a case where silicon oxide is used, there can be formed the gate insulating film 12 of higher quality.

In the first embodiment, the gate electrode 14 is formed from polysilicon. However, the present invention is not limited to such a material. As shown in FIG. 4, the gate insulating film 12 may be formed from material having a high dielectric constant (e.g., ZrO₂), and the gate electrode 14 may be formed from metal material such as tungsten. In the present embodiment, since no high temperature is applied to the gate electrode 14, the high-quality gate electrode 14 can be embodied by means of adoption of the construction shown in FIG. 4.

Second Embodiment

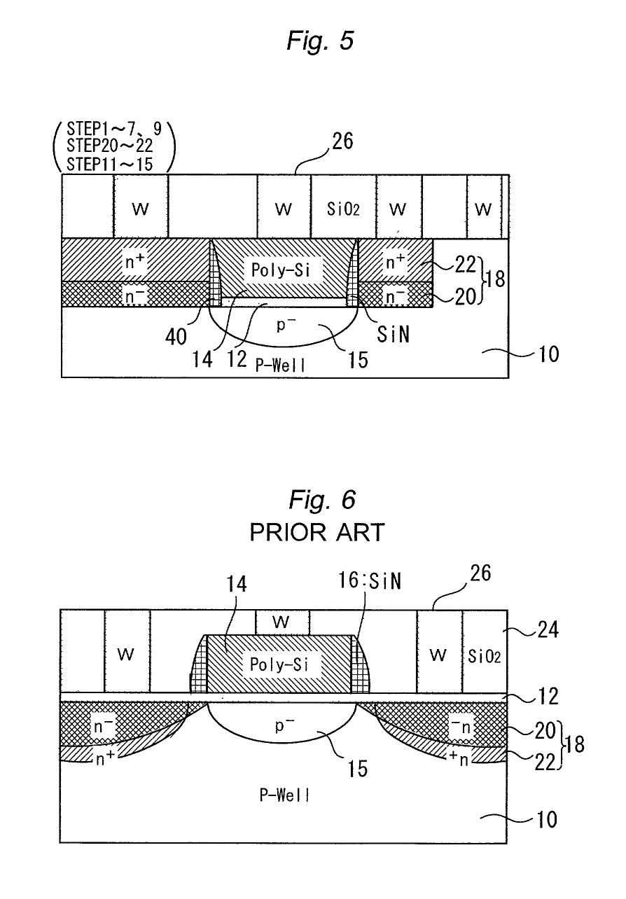

A second embodiment of the present invention will now be described by reference to FIG. 5.

FIG. 5 is a cross-sectional view of a MOSFET belonging to the semiconductor device according to the second embodiment. As shown in FIG. 5, a sidewall 40 is provided in a boundary region between each side of the gate electrode 14 and the source/drain region 18, and the gate oxide film 12 is provided only below the bottom of the gate electrode 14. The sidewall 40 is a multilayered film consisting of a silicon nitride film (SiN) and a pad oxide film (SiO₂).

The MOSFET according to the present embodiment can be manufactured according to the following procedures. (Steps 1 through 5) The silicon substrate assumes the construction shown in FIG. 2 by being subjected to processing steps 1 through 5 as with in the case of the first embodiment. (Steps 6 and 7) A pad oxide film (not shown) of about 10 nm thickness and the channel region 15 shown in FIG. 3 are formed through processing pertaining to steps 6 and 7 as with the case of the first embodiment.

A (Step 9) The silicon substrate is subjected to heat treatment required for activating the impurities implanted in the source/drain region 18 and those implanted in the channel region 15. As in the case of the first embodiment, the silicon substrate maybe subjected to heat treatment at any timing before formation of the gate insulating film 12 and the gate electrode 14.

(Step 20) A silicon nitride film is deposited on the entire surface of the pad oxide film overlying the silicon substrate by means of the CVD technique.

(Step 21) The silicon nitride film and the pad oxide film are removed from the trench 30 by means of an isotropic etching, with the exception of those attaching to the side walls of the trench 30. As a result, side walls 40 shown in FIG. 5 are formed.

(Step 22) The gate oxide film 12 is formed on the surface of the p-well 10 exposed on the bottom of the trench 30 by means of the CVD technique or the thermal oxidation technique.

(Steps 11 through 15) The gate electrode 14 and the contact plug 26 are formed in the same manner as in the first embodiment, whereby the silicon substrate assumes the construction shown in FIG. 5.

As mentioned above, in the present embodiment, the sidewall 40 including the silicon nitride film can be interposed between the gate electrode 14 and the source/drain region 18. In this case, the influence which is exerted on the source/drain region 18 by a gate voltage can be diminished, thereby stabilizing the electrical characteristics of a transistor.

Since the present invention has been embodied in the manner as mentioned previously, the following advantages are yielded.

According to a first aspect of the present invention, a gate insulating film and a gate electrode can be formed after formation of source/drain regions. Accordingly, the present invention can obviate application of high temperature to the gate insulating film and the gate electrode, thereby implementing a semiconductor device of stable quality. In addition, according to the present invention, the surface of the gate electrode and the surfaces of the source/drain regions are made smooth. Even under the circumstance where demand exists for a high degree of integration, an interconnection layer of stable quality can be formed on the gate electrode and the source/drain regions.

According to a second aspect of the present invention, the source/drain regions can be formed into an LDD structure, while a construction in which a gate electrode is sandwiched between a pair of source/drain regions is employed.

According to a third aspect of the present invention, the source/drain regions and the gate electrode can be formed so as to assume the same thickness, while a construction in which a gate electrode is sandwiched between a pair of source/drain regions is employed.

According to a fourth aspect of the present invention, a gate insulating film can be formed from material having a high dielectric constant, since high temperature is not applied to the gate insulating film. Accordingly, the present invention enables implementation of a semiconductor device having a high-quality gate insulating film.

According to a fifth aspect of the present invention, a gate electrode can be made of metal material, since no high temperature is applied to the gate electrode. Accordingly, the present invention enables implementation of a semiconductor device having a high-quality gate electrode.

According to a sixth aspect of the present invention, a sidewall including a silicon nitride film can be interposed between each of the source/drain regions and the gate electrode, while a construction in which a gate electrode is sandwiched between a pair of source/drain regions is employed. In this case, the influence exerted on the source/drain regions by a gate potential is reduced, thereby stabilizing the electrical characteristics of a semiconductor device.

According to a seventh aspect of the present invention, the surface of the gate electrode and the surfaces of the source/drain regions can be made smooth easily by means of the etch-back technique.

According to a eighth aspect of the present invention, the surface of the gate electrode and the surfaces of the source/drain regions can be made smooth easily by means of the CMP technique.

Further, the present invention is not limited to these embodiments, but variations and modifications may be made without departing from the scope of the present invention.

The entire disclosure of Japanese Patent Application No. 2000-271025 filed on Sep. 7, 2000 including specification, claims, drawings and summary are incorporated herein by reference in its entirety.

What is claimed is:

1. A semiconductor device comprising:
a gate electrode;
a gate insulating film covering the side surfaces and bottom surface of the gate electrode;
a pair of source/drain regions which are provided by way of the gate insulating film such that the gate electrode is interposed between the source/drain regions; and
a channel region formed below the gate electrode with the gate insulating film therebetween, wherein the surface of the gate electrode and the surfaces of the source/drain regions constitute a single flat surface.

2. The semiconductor device according to claim 1, wherein each of the source/drain regions has a low-concentration impurity region containing a low concentration of impurities and a high-concentration impurity region containing a high concentration of impurities, the high-concentration impurity region being formed on the low-concentration impurity region.

3. The semiconductor device according to claim 1, wherein the depth of the bottom surface of the gate insulating film accords with that of the bottom surfaces of the source/drain regions.

4. The semiconductor device according to claim 1, wherein the gate insulating film is made of material having a dielectric constant higher than that of a silicon oxide film.

5. The semiconductor device according to claim 1, wherein the gate electrode is made of metal material.

6. The semiconductor device according to claim 1, further comprising sidewalls, each containing a silicon nitride film and being interposed between a side surface of the gate electrode and a side surface of corresponding source/drain region.

7. A method of manufacturing a semiconductor device comprising:
a step of forming a first-type well by means of implanting impurities of first conductivity type into a silicon substrate;
a step of forming source/drain regions by means of implanting impurities of second conductivity type into the first-type well to a predetermined depth;
a step of forming a trench in the first-type well so as to be sandwiched between the source/drain regions, by means of removing predetermined portions of the source/drain regions;
a step of forming a gate insulating film so as to cover the side surfaces of the trench and the surface of the first-type well exposed on the bottom of the trench;
a step of embedding conductive material in the trench covered with the gate insulating film;
a step of forming a gate electrode in the trench by means of removal of the portion of the conductive material existing out of the trench; and
a step of forming an interconnection layer on a layer to which the source/drain regions and the gate electrode pertain.

8. The method of manufacturing a semiconductor device according to claim 7, wherein the step of removing the portion of the conductive material existing out of the trench further includes a step of etching back the conductive material until the surface of the gate electrode and the surfaces of the source/drain regions become smooth.

9. The method of manufacturing a semiconductor device according to claim 7, wherein the step of removing the portion of the conductive material lying off the trench further includes a step of removing the conductive material by means of CMP until the surface of the gate electrode and the surfaces of the source/drain regions become smooth.

10. The method of manufacturing a semiconductor device according to any one of claim 7, wherein the step of forming the source/drain regions comprises
a step of forming a low-concentration impurity region in the first-type well by means of implanting the impurities of second type to a first depth and at a first concentration; and
a step of forming a high-concentration impurity region in the first-type well by means of implanting the impurities of second type to a second depth deeper than the first depth, such that the high-concentration impurity region is formed on the low-concentration impurity region.

11. The method of manufacturing a semiconductor device according to any one of claim 7, wherein the trench is formed such that the depth of the bottom surface of the trench accords with that of the bottom surfaces of the source/drain regions.

12. The method of manufacturing a semiconductor device according to any one of claim 7, wherein the gate insulating film is made of material having a dielectric constant higher than that of the silicon oxide film.

13. The method of manufacturing a semiconductor device according to any one of claim 7, wherein the gate electrode is made of metal material.

14. A method of manufacturing a semiconductor device comprising:
a step of forming a first-type well by means of implanting impurities of first conductivity type into a silicon substrate;
a step of forming source/drain regions by means of implanting impurities of second conductivity type into the first-type well to a predetermined depth;
a step of forming a trench in the first-type well so as to be sandwiched between the source/drain regions, by means of removing predetermined portions of the source/drain regions;
a step of forming a sidewall containing a silicon nitride film and covering a side surface of the gate electrode;
a step of forming a gate insulating film so as to cover the surface of the first-type well exposed in the bottom of the trench;
a step of embedding with conductive material the trench covered with the sidewalls and the gate insulating film;
a step of forming a gate electrode in the trench by means of removing the portion of the conductive material existing out of the trench; and
a step of forming an interconnection layer on a layer to which the source/drain regions and the gate electrode pertain.

15. The method of manufacturing a semiconductor device according to claim 14, wherein the step of removing the portion of the conductive material existing out of the trench further includes a step of etching back the conductive material until the surface of the gate electrode and the surfaces of the source/drain regions become smooth.

16. The method of manufacturing a semiconductor device according to claim 14, wherein the step of removing the portion of the conductive material lying off the trench further includes a step of removing the conductive material by means of CMP until the surface of the gate electrode and the surfaces of the source/drain regions become smooth.

17. The method of manufacturing a semiconductor device according to claim 14, wherein the step of forming the source/drain regions comprises
a step of forming a low-concentration impurity region in the first-type well by means of implanting the impurities of second type to a first depth and at a first concentration; and
a step of forming a high-concentration impurity region in the first-type well by means of implanting the impurities of second type to a second depth deeper than the first depth, such that the high-concentration impurity region is formed on the low-concentration impurity region.

18. The method of manufacturing a semiconductor device according to claim 14, wherein the trench is formed such that the depth of the bottom surface of the trench accords with that of the bottom surfaces of the source/drain regions.

19. The method of manufacturing a semiconductor device according to claim 14, wherein the gate insulating film is made of material having a dielectric constant higher than that of the silicon oxide film.

20. The method of manufacturing a semiconductor device according to claim 14, wherein the gate electrode is made of metal material.
